(19) United States
(12) Patent Application Publication
(10) Pub. No.: US 2020/0152739 A1
(43) Pub. Date: May 14, 2020

(54) TRANSISTORS WITH LOW CONTACT RESISTANCE AND METHOD OF FABRICATING THE SAME

(71) Applicant: QUALCOMM Incorporated, San Diego, CA (US)

(72) Inventors: Bin Yang, San Diego, CA (US); Xia Li, San Diego, CA (US); Gengming Tao, San Diego, CA (US); Ye Lu, San Diego, CA (US)

(21) Appl. No.: 16/189,855

(22) Filed: Nov. 13, 2018

(51) Int. Cl. H01L 29/08; H01L 29/24; H01L 29/10; H01L 29/51; H01L 29/78; H01L 21/768; H01L 21/02

(52) U.S. Cl. CPC H01L 29/0847; H01L 29/24; H01L 29/1033; H01L 21/02568; H01L 29/78; H01L 21/76829; H01L 21/0228; H01L 29/517

(57) ABSTRACT

A transistor comprises a substrate, a first buffer layer on the substrate, a source region, a drain region, and a channel region on the first buffer layer, a gate on the channel region, a source contact, and a drain contact. The source contact is configured to contact at least three sides of the source region and the drain contact is configured to contact at least three sides of the drain region to lower contact resistance in the source region and in the drain region.

### BACKGROUND

### Field

Certain aspects of the present disclosure generally relate to transistors, and more particularly, to transistors with low contact resistance in source region and in drain region.

### Background

Internet of Things (IoT) comprises a network of various devices. It enables these devices to connect with each other and exchange information. IoT extends internet connectivity beyond traditional network devices, such as smartphones and computers, to many everyday objects. For example, IoT makes it possible to connect an air conditioner with a smartphone to adjust temperature of a room remotely. The market of IoT is growing year over year and will reach shipment of around 30 billion devices with a market value of approximately 7 trillion dollars by 2020.

IoT applications generally require low power consumption and long battery life. IoT devices are often referred to as set and forget devices intended to run more than 10 years without replacing battery. This requirement poses serious challenges for existing Complementary Metal Oxide Semiconductor (CMOS) devices, because current CMOS devices are unable to meet such low power consumption requirements.

In recent years, Molybdenum Disulfide (MoS₂) has been demonstrated to provide good mobility and room temperature current on/off ratio for fabricating transistors with ultralow power dissipation. Thus, MoS₂ based transistors may be employed to satisfy the power consumption requirements for IoT applications. FIG. 1 illustrates an exemplary transistor 100 based on MoS₂. The transistor 100 comprises a substrate 102. The substrate 102 may comprise Silicon (Si) or other substrate materials. The transistor 100 further comprises a Silicon Dioxide (SiO₂) layer 104 on the substrate 102, a MoS₂ layer 106 on the SiO₂ layer 104, and a Hafnium Oxide (HfO₂) layer 108 on the MoS₂ layer 106. The MoS₂ layer 106 forms a source region, a drain region, and a channel region for the transistor 100. The HfO₂ layer 108 forms a gate dielectric layer for the transistor 100. The transistor 100 further comprises a gate 110, gate spacers 112, a source contact 114, a drain contact 116, contact vias 118, and a dielectric layer 120. Each of the source contact 114 and the drain contact 116 comprises Gold (Au) and Titanium (Ti) and forms ohmic contacts with the MoS₂ layer 106. One major concern for the transistor 100 is high contact resistance in the source region and in the drain region at interfaces between the source contact 114, the drain contact 116 and the MoS₂ layer 106. The high contact resistance can deteriorate performance of the transistor 100. Thus, there is a need for a transistor with low contact resistance in source region and in drain region for IoT applications.

### SUMMARY

Certain aspects of the present disclosure provide a transistor. The transistor may include a substrate. The transistor may also include a first buffer layer on the substrate. The transistor may also include a source region, a drain region, and a channel region on the first buffer layer. The transistor may also include a gate on the channel region. The transistor may further include a source contact configured to contact at least three sides of the source region and a drain contact configured to contact at least three sides of the drain region.

Certain aspects of the present disclosure provide a method for fabricating a transistor. The method may include forming a plurality of layers on a substrate. The method may also include forming a gate region on the plurality of layers. The method may also include forming a semiconductor layer to form a source region and a drain region. The method may also include forming a contact layer on the semiconductor layer, wherein the contact layer is configured to contact at least three sides of the semiconductor layer in the source region and in the drain region. The method may further include forming a dielectric layer and contacts.

This summary has outlined the features and embodiments of the present disclosure so that the following detailed description may be better understood. Additional features and embodiments of the present disclosure will be described below. It should be appreciated by those skilled in the art that this disclosure may be readily utilized as a basis for modifying or designing other equivalent structures for carrying out the same purposes of the present disclosure. It should also be realized by those skilled in the art that such equivalent constructions do not depart from the teachings of the present disclosure as set forth in the appended claims. The features, which are believed to be characteristic of the present disclosure, both as to its organization and method of operation, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates an exemplary transistor based on Molybdenum Disulfide (MoS₂);

FIG. 2 illustrates an exemplary transistor with low contact resistance in source region and in drain region in accordance with certain aspects of the present disclosure; and

FIGS. 3A-3D illustrate an exemplary fabrication process for the exemplary transistor of FIG. 2 in accordance with certain aspects of the present disclosure.

### DETAILED DESCRIPTION

With reference to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The detailed description set forth below, in connection with the appended drawings, is intended as a description of various aspects and is not intended to represent the only aspect in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

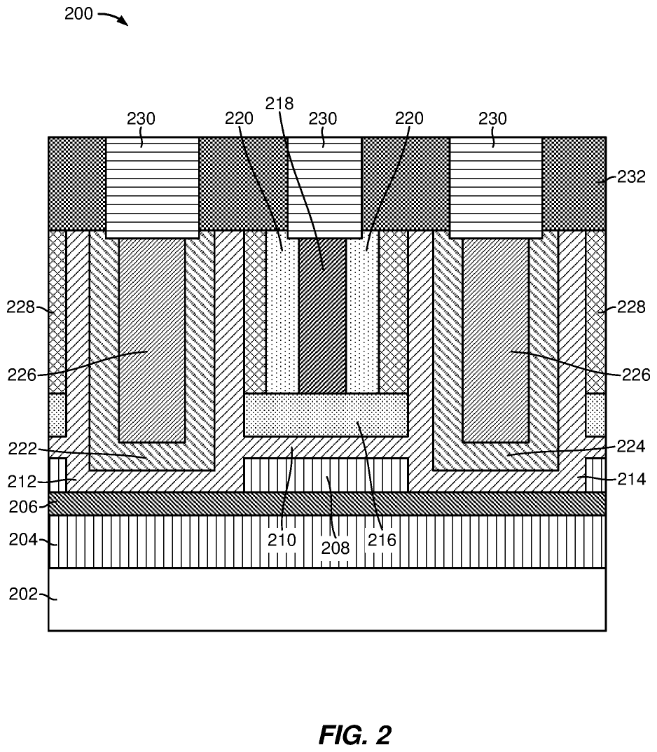

FIG. 2 illustrates an exemplary transistor with low contact resistance in source region and in drain region in accordance with certain aspects of the present disclosure. As an example, the exemplary transistor may be based on Molybdenum Disulfide (MoS₂) and may be used for IoT applications. A transistor 200 is shown in FIG. 2. The transistor 200 comprises a substrate 202. As an example, the substrate 202 may comprise Silicon (Si) or other substrate materials, such as glass. The transistor 200 also comprises a first buffer layer 204 on the substrate 202. As an example, the first buffer layer 204 may comprise Silicon Dioxide (SiO₂). The transistor 200 also comprises an etch stop layer 206 on the first buffer layer 204. As an example, the etch stop layer 206 may comprise Aluminum Oxide (Al₂O₃), Aluminum Nitride (AlN), or Silicon Nitride (SiN). The transistor 200 may also comprise a second buffer layer 208 on the etch stop layer 206. As an example, the second buffer layer 208 may comprise SiO₂. The transistor 200 also comprises a source region 212 on the etch stop layer 206, a drain region 214 on the etch stop layer 206, and a channel region 210 between the source region 212 and the drain region 214. As an example, the source region 212, the drain region 214, and the channel region 210 may comprise MoS₂. The channel region 210 may be on the second buffer layer 208. Alternatively, the channel region 210 may be on the etch stop layer 206 without the second buffer layer 208 between the channel region 210 and the etch stop layer 206. The second buffer layer 208 may be employed to improve quality of MoS₂ deposition in the channel region 210. The transistor 200 also comprises a gate dielectric layer 216 on the channel region 210, and a gate 218 and gate spacers 220 on the gate dielectric layer 216. As an example, the gate dielectric layer 216 may comprise Hafnium Oxide (HfO₂), the gate 218 may comprise Titanium (Ti), Titanium Nitride (TiN), and Tungsten (W), and the gate spacers 220 may comprise SiN, SiO₂, or Silicon Oxycarbonitride (SiCNO). The transistor 200 also comprises a source contact 222, a drain contact 224, contact vias 226, and a first dielectric layer 228. As an example, the source contact 222 and the drain contact 224 may comprise Gold (Au) and Titanium (Ti) and form ohmic contacts with the source region 212 and the drain region 214. The contact vias 226 may comprise W and the first dielectric layer 228 may comprise Silicon Oxynitrocarbide (SiONC). The transistor 200 further comprises contacts 230 for the contact vias 226 and the gate 218 and a second dielectric layer 232. As an example, the contacts 230 may comprise W. The second dielectric layer 232 may comprise SiO₂ or Silicon Oxynitride (SiON).

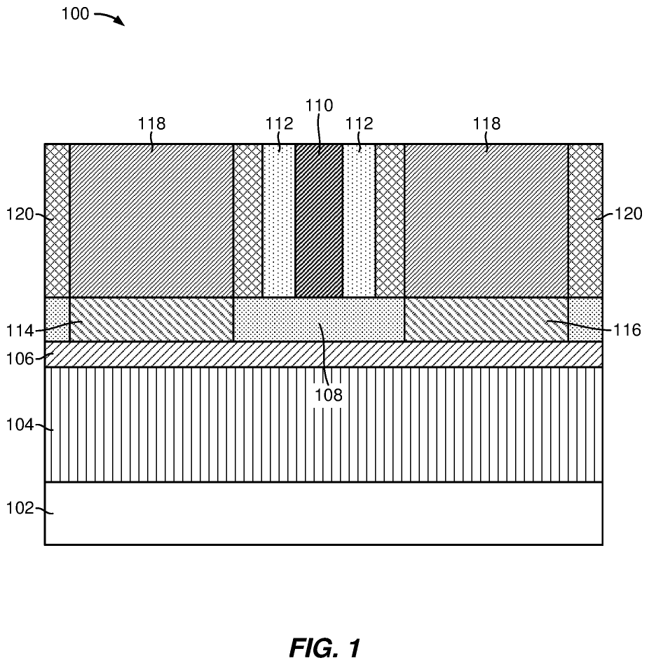

With continuing reference to FIG. 2, contact resistance in the source region 212 and in the drain region 214 is lower in the transistor 200 than the contact resistance in the source region and in the drain region in the transistor 100, because the transistor 200 has larger contact area in the source region and in the drain region compared to the transistor 100. In the transistor 100, the source contact 114 contacts the source region with a single side of the source region as shown in FIG. 1. Similarly, the drain contact 116 contacts the drain region with a single side of the drain region as shown in FIG. 1. In the transistor 200, the source contact 222 contacts the source region 212 with three different sides of the source region 212 as shown in FIG. 2. Similarly, the drain contact 224 contacts the drain region 214 with three different sides of the drain region 214 as shown in FIG. 2. Thus, for a same transistor size, the transistor 200 has larger contact area compared to the transistor 100 in the source region and in the drain region. The larger contact area will result in a lower contact resistance and improved transistor performance for the transistor 200, which can be employed for various IoT applications.

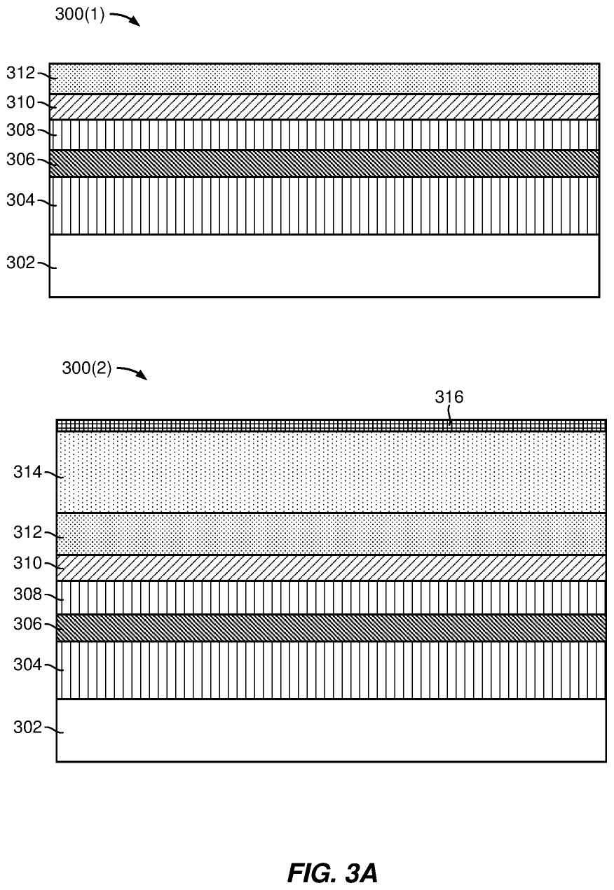

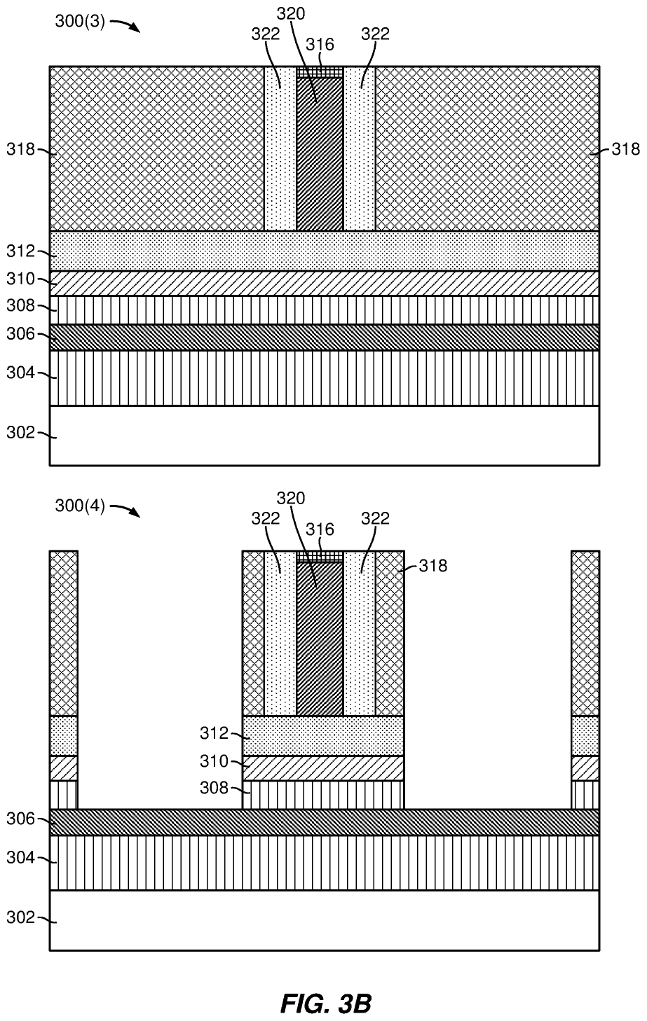

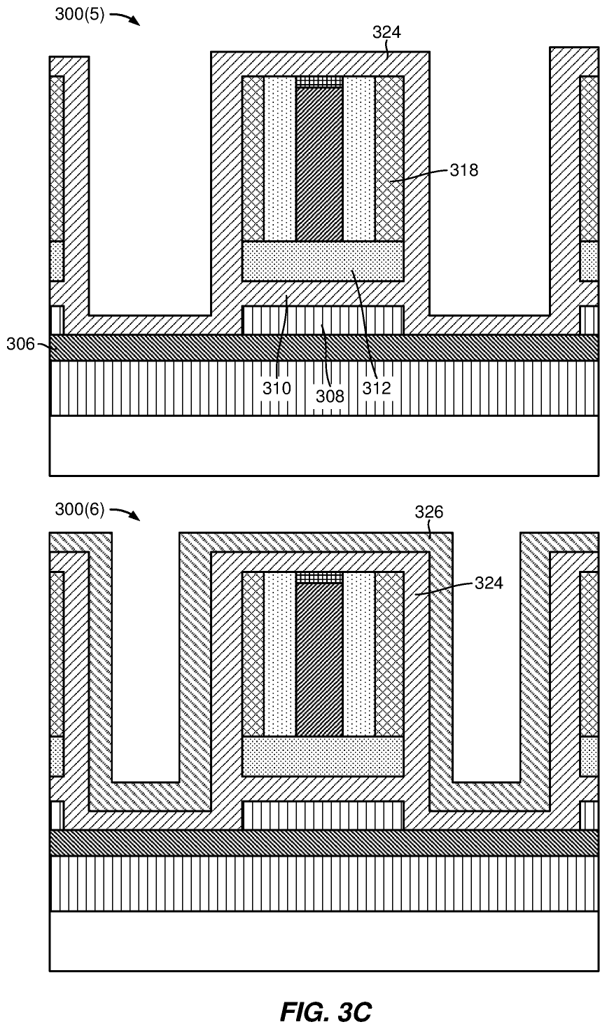

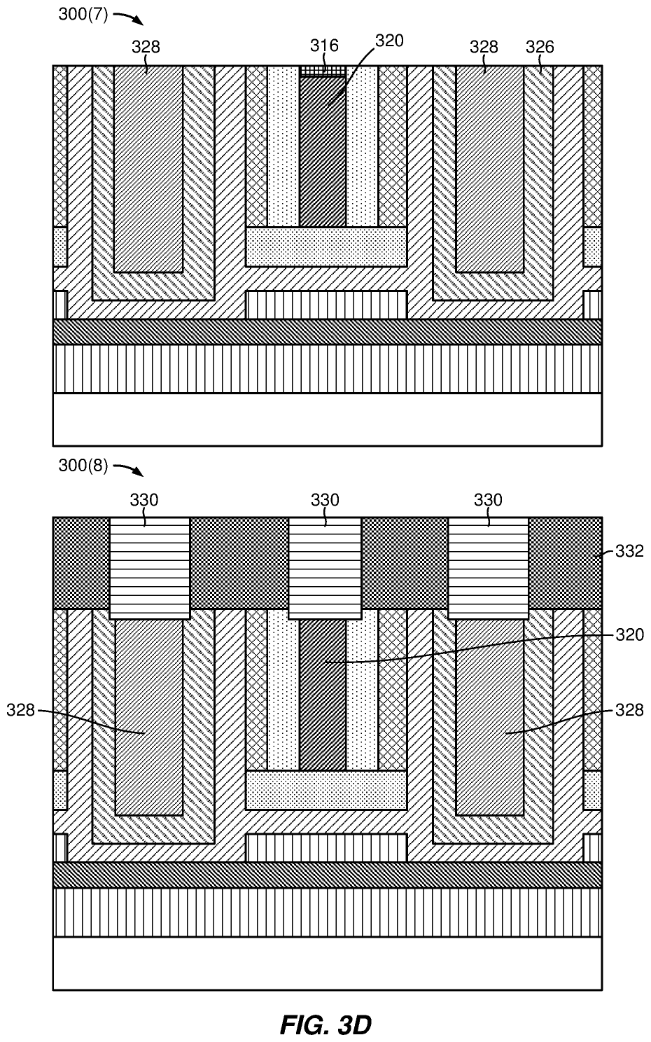

FIGS. 3A-3D illustrate an exemplary fabrication process for the transistor 200 in FIG. 2 in accordance with certain aspects of the present disclosure. In FIG. 3A, stage 300(1) includes forming a first buffer layer 304 on a substrate 302. As an example, the substrate 302 may comprise Si or other substrate materials, such as glass. The first buffer layer 304 may comprise SiO₂. The stage 300(1) also includes forming an etch stop layer 306 on the first buffer layer 304. As an example, the etch stop layer 306 may comprise Al₂O₃, AlN, or SiN. The etch stop layer 306 may be formed by Physical Vapor Deposition (PVD) or Chemical Vapor Deposition (CVD). The stage 300(1) also includes forming a second buffer layer 308 on the etch stop layer 306. As an example, the second buffer layer 308 may comprise SiO₂. The stage 300(1) also includes forming a first semiconductor layer 310 on the second buffer layer 308. As an example, the first semiconductor layer 310 may comprise MoS₂. The first semiconductor layer 310 may be formed by Atomic Layer Deposition (ALD) or CVD. As mentioned above, the second buffer layer 308 may be employed to improve quality of MoS₂ deposition for the first semiconductor layer 310. The stage 300(1) further includes forming a gate dielectric layer 312 on the first semiconductor layer 310. As an example, the gate dielectric layer 312 may comprise HfO₂. The gate dielectric layer 312 may be formed by ALD.

With continuing reference to FIG. 3A, stage 300(2) includes forming a metal gate layer 314 on the gate dielectric layer 312. As an example, the metal gate layer 314 may comprise Ti, TiN, and W. The stage 300(2) further includes forming a first dielectric layer 316 on the metal gate layer 314. As an example, the first dielectric layer 316 may comprise SiN.

In FIG. 3B, stage 300(3) includes patterning the metal gate layer 314 and the first dielectric layer 316 to form a gate 320. The gate 320 is covered by a remaining portion of the first dielectric layer 316. The stage 300(3) also includes forming gate spacers 322 on each side of the gate 320. As an example, the gate spacers 322 may comprise SiN, SiO₂, or SiCNO. The stage 300(3) further includes forming a second dielectric layer 318 and performing Chemical Mechanical Polishing (CMP) to planarize the second dielectric layer 318 until the remaining portion of the first dielectric layer 316 is exposed. The remaining portion of the first dielectric layer 316 may be employed to protect the gate 320 during the CMP. As an example, the second dielectric layer 318 may comprise SiONC. The second dielectric layer 318 may be formed by CVD.

With continuing reference to FIG. 3B, stage 300(4) includes patterning the second dielectric layer 318, the gate dielectric layer 312, the first semiconductor layer 310, and the second buffer layer 308. As an example, patterning the second dielectric layer 318 may comprise removing the second dielectric layer 318 by dry etching. Patterning the gate dielectric layer 312, the first semiconductor layer 310, and the second buffer layer 308 may comprise removing the gate dielectric layer 312, the first semiconductor layer 310, and the second buffer layer 308 by dry etching. The dry etching may stop on the etch stop layer 306.

In FIG. 3C, stage 300(5) included forming a second semiconductor layer 324. The second semiconductor layer 324 forms a conformal layer on the etch stop layer 306 and on sidewalls of the second buffer layer 308, the first semiconductor layer 310, the gate dielectric layer 312, and the second dielectric layer 318. As an example, the second semiconductor layer 324 may comprise same material as the first semiconductor layer 310, such as MoS₂. The second semiconductor layer 324 may be formed by ALD or CVD. The first semiconductor layer 310 forms a channel region and the second semiconductor layer 324 forms a source region and a drain region for a transistor.

With continuing reference to FIG. 3C, stage 300(6) includes forming a contact layer 326 on the second semiconductor layer 324. The contact layer 326 forms a conformal layer on the second semiconductor layer 324. As an example, the contact layer 326 may comprise Au and Ti. The contact layer 326 may be formed by ALD or PVD. The contact layer 326 forms ohmic contacts with the second semiconductor layer 324 in the source region and in the drain region. As mentioned above, the contact layer 326 contacts the source region with three different sides of the source region and contacts the drain region with three different sides of the drain region as shown in the stage 300(6). Thus, a larger contact area could be achieved in the source region and in the drain region, which will result in a lower contact resistance and improved transistor performance.

In FIG. 3D, stage 300(7) includes forming contact vias 328. As an example, the contact vias 328 may comprise W. The contact vias 328 may be formed by forming a contact via layer on the contact layer 326 by PVD and performing CMP to planarize the contact via layer until the remaining portion of the first dielectric layer 316 is exposed. As mentioned above, the remaining portion of the first dielectric layer 316 may be employed to protect the gate 320 during the CMP.

With continuing reference to FIG. 3D, stage 300(8) includes forming a third dielectric layer 332 and forming contacts 330 for the contact vias 328 and the gate 320. As an example, the third dielectric layer 332 may comprise SiO₂ or SiON. The contacts 330 may comprise W. The contacts 330 may be formed by patterning the third dielectric layer 332, removing the remaining portion of the first dielectric layer 316, and depositing the contacts 330 for the contact vias 328 and the gate 320.

The transistor with low contact resistance in source region and in drain region according to certain aspects disclosed herein may be provided in or integrated into any electronic device. Examples, without limitation, include a set top box, an entertainment unit, a navigation device, a communication device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, and a drone.

Those of skill in the art will further appreciate that the various illustrative logical blocks, modules, circuits, and algorithms described in connection with the certain aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in any flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and features disclosed herein.

1. A transistor, comprising:
a substrate;
a first buffer layer on the substrate;
a source region, a drain region, and a channel region on the first buffer layer;
a gate on the channel region;
a source contact configured to contact at least three sides of the source region; and
a drain contact configured to contact at least three sides of the drain region.

2. The transistor of claim 1, wherein the first buffer layer comprises Silicon Dioxide (SiO₂).

3. The transistor of claim 1, wherein the source region, the drain region, and the channel region comprise Molybdenum Disulfide (MoS₂).

4. The transistor of claim 1, wherein each of the source contact and the drain contact comprises Gold (Au) and Titanium (Ti).

5. The transistor of claim 1, further comprising an etch stop layer between the first buffer layer and the source region, the drain region, and the channel region.

6. The transistor of claim 5, wherein the etch stop layer comprises at least one of Aluminum Oxide (Al₂O₃), Aluminum Nitride (AlN), and Silicon Nitride (SiN).

7. The transistor of claim 5, further comprising a second buffer layer between the etch stop layer and the channel region.

8. The transistor of claim 7, wherein the second buffer layer comprises SiO₂.

9. The transistor of claim 1, further comprising a gate dielectric layer between the channel region and the gate.

10. The transistor of claim 9, wherein the gate dielectric layer comprises Hafnium Oxide (HfO₂).

11. The transistor of claim 1, further comprising contact vias in contact with the source contact and the drain contact.

12. The transistor of claim 11, wherein the contact vias comprise Tungsten (W).

13. A method for fabricating a transistor, comprising:
forming a plurality of layers on a substrate;
forming a gate region on the plurality of layers;
forming a semiconductor layer to form a source region and a drain region;
forming a contact layer on the semiconductor layer, wherein the contact layer is configured to contact at least three sides of the semiconductor layer in the source region and in the drain region; and
forming a dielectric layer and contacts.

14. The method of claim 13, wherein the plurality of layers comprises a first buffer layer and a second buffer layer, and wherein the first buffer layer and the second buffer layer comprise Silicon Dioxide (SiO₂).

15. The method of claim 13, wherein the semiconductor layer comprises Molybdenum Disulfide (MoS₂).

16. The method of claim 13, wherein the semiconductor layer is formed by Atomic Layer Deposition (ALD).

17. The method of claim 13, wherein the plurality of layers comprises a gate dielectric layer, and wherein the gate dielectric layer comprises Hafnium Oxide (HfO₂).

18. The method of claim 13, wherein the plurality of layers comprises an etch stop layer, and wherein the etch stop layer comprises at least one of Aluminum Oxide (Al₂O₃), Aluminum Nitride (AlN), and Silicon Nitride (SiN).

19. The method of claim 13, wherein the contact layer comprises Gold (Au) and Titanium (Ti).

20. The method of claim 13, wherein the dielectric layer comprises at least one of SiO₂ and Silicon Oxynitride (SiON).
